(19) United States
(12) Patent Application Publication
(10) Pub. No.: US 2006/0275672 A1
(43) Pub. Date: Dec. 7, 2006

(54) Photomask with controllable patterns

(75) Inventors: Chien-Chung Kuo, Taichung County (TW); Chin-Chang Liu, Taichung County (TW)

Correspondence Address: BIRCH STEWART KOLASCH & BIRCH, PO BOX 747, FALLS CHURCH, VA, 22040-0747, US

(73) Assignee: WINTEK CORPORATION

(21) Appl. No.: 11/144,821

(22) Filed: Jun. 6, 2005

(51) Int. Cl. G03F 1/00

(52) U.S. Cl. 430/5

(57) ABSTRACT

A photomask with controllable patterns is a panel, which can be controlled to change the shading patterns. The panel is composed of a plurality of optical controlled elements and has various portions of transparent, gray-scale or opaque patterns by controlling the optical controlled elements. When light passes through the photomask, the arrangement of the transparent, semiopaque, and opaque optical controlled elements forms the shading patterns, and these are exposure patterns in the exposure process.

### FIELD OF THE INVENTION

The present invention relates to a photomask with controllable patterns, more particularly to a photomask which exposure patterns can be modified easily and be reused.

### BACKGROUND OF THE INVENTION

In traditional photolithography processes, the patterns of photoresist are developed through the exposure of a photomask before the etching process. However, a lot of photomasks are needed for manufacturing a device, and each photomask is expensive and has a unique pattern. Therefore, it cannot alter the fixed patterns of the photomask for design modification or pattern re-definition in the development of new products or technologies. Besides, it is not easy to repair the imperfection of the photomask, if necessary. All above disadvantages will cause an abundance of funds for developing products.

In addition, a lot of photomasks with different patterns will cause disorder and increases the cost for product management, which is a burden to a user. Furthermore, the photomask for old product is nullified when the new product replaced the old one.

### SUMMARY OF THE INVENTION

Therefore, in order to solve the above problems, the primary objective of the present invention is to use optical controlled elements as a photomask, which can be reused according to the difference between the new and old design of products, thereby reducing the funds of research efficiently.

Another objective of the present invention is to use optical controlled elements as a photomask, which can modify the processes and the design of circuits efficiently due to changeability of the photomask patterns, and thereby obtaining the optimum parameters of the exposure process and the better processes for patterning.

The other objective is that the present invention uses optical controlled elements as a photomask, which can generate the function of gray-scale photomasks to control the exposure density of one pattern in different areas for the requirement of special processes.

The present invention presents the photomask with shading patterns for the exposure process. The feature is that the photomask is a panel, which can be controlled to change the shading patterns. The panel composed of a plurality of optical controlled elements and forms various portions of transparent, semiopaque, and opaque patterns by controlling the optical controlled elements and through outputting the data of exposure patterns from the control system. When light passes through the transmissive photomask, the arrangement of the transparent, semiopaque, and opaque optical controlled elements forms the shading patterns, and these are the exposure patterns in the exposure process.

Therefore, the photomask can be reused and modifies the processes and the layout design efficiently in the development stage of products, so that the optimum parameters of the exposure process can be obtained and the time for inspection and modification of new products can be reduced.

### BRIEF DESCRIPTION OF THE DRAWINGS

FIG. 1 shows a schematic diagram of exposure intensity of the transmissive photomask of the present invention.

FIG. 2 shows a schematic diagram of exposure intensity of the transmissive gray-scale photomask of the present invention.

FIG. 3 shows a schematic diagram of exposure intensity of the reflective photomask of the present invention.

FIG. 4 shows a schematic diagram of exposure intensity of the reflective gray-scale photomask of the present invention.

### DETAILED DESCRIPTION OF THE PREFERRED EMBODIMENTS

The detail contents and illustrations of the technologies of the invention are given below.

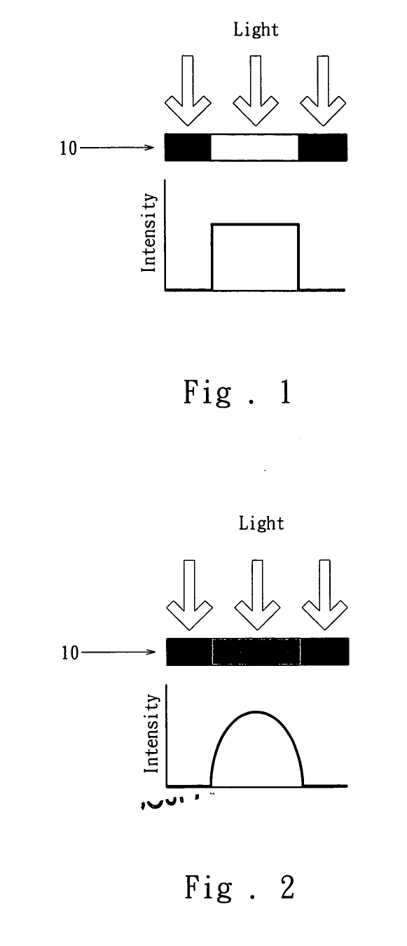

FIG. 1 shows the schematic diagram of exposure intensity of the transmissive photomask of the present invention. The invention presents a photomask 10 with shading patterns for the exposure process. The feature is that the photomask 10 is a panel, which can be controlled to change the shading patterns. The panel is composed of a plurality of a plurality of optical controlled elements. The photomask 10 is a transmissive liquid crystal panel or a transmissive electronic paper. Through the transmissive liquid crystal panel or the transmissive electronic paper that composed of a plurality of optical controlled elements (pixels) and by outputting the data of the exposure patterns transmitted from the suitable control system, the optical controlled elements form various portions of transparent and opaque patterns on the photomask 10. When light passes through the transmissive photomask 10, the arrangement of the transparent and opaque optical controlled elements forms the shading patterns, and these are exposure patterns in the exposure process.

Of course, we can take the advantage of the characteristics of the transmissive liquid crystal panel or the electronic paper of the photomask 10 to form the gray-scale patterns between the transparent and the opaque patterns, and thereby control the exposure intensity, as shown in FIG. 2. When light passes through the transmissive photomask 10, the arrangement of the transparent, semiopaque and opaque optical controlled elements forms the shading patterns, and thereby controlling the exposure pattern and the exposure intensity for the requirement of special processes.

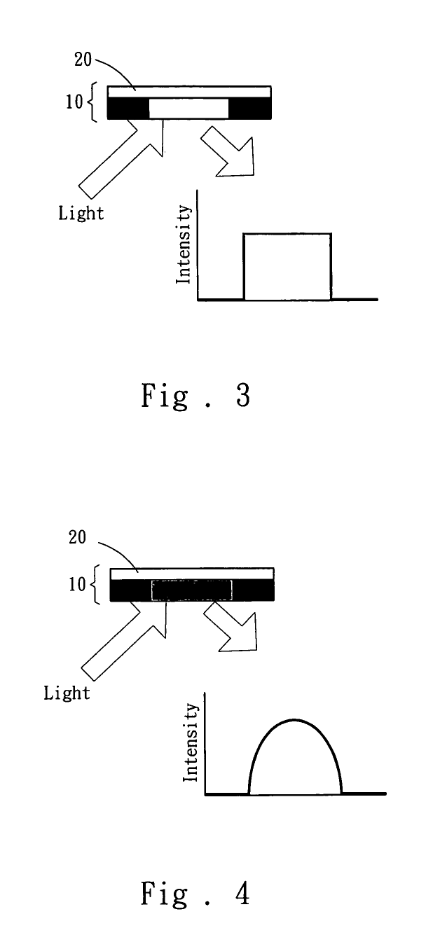

FIG. 3 shows the schematic diagram of exposure intensity of the reflective photomask of the present invention. It is another executive state. The reflective photomask 10 is a liquid crystal panel or an electronic paper with a reflective layer 20. Through the transmissive liquid crystal panel or the electronic paper, which composed of a plurality of optical controlled elements (pixels) and by outputting the data of the exposure patterns transmitted from the suitable control system, the optical controlled elements are controlled to form various portions of transparent and opaque patterns on the photomask 10. When light passes through the transmissive panel of the photomask 10, the arrangement of the transparent and opaque optical controlled elements forms shading patterns, and these are the exposure patterns in the exposure process when light passes through the transparent area of the photomask 10 and reflects from the reflective layer 20.

Of course, we can take the advantage of the characteristics of the transmissive liquid crystal panel or the electronic paper of the photomask 10 to form the gray-scale pattern between the transparent and the opaque patterns, and thereby controlling the exposure intensity, as shown in FIG. 4. When light passes through the transmissive panel of photomask 10, the arrangement of the transparent, semiopaque and opaque optical controlled elements forms shading patterns. When light passes through the transparent or the gray-scale area of the photomask 10 and reflects from the reflective layer 20, the exposure pattern and the exposure intensity are controlled for the requirement of special processes.

Furthermore, the controllable and reflective photomask 10 can be a digital micro-mirror device (DMD). The DMD is composed of several hundred thousands of micro-mirrors. The micro-mirror is smaller than the cross section of hair. The resolution of the device can be upgraded by increasing the numbers of the micro-mirrors inside the DMD but without changing the size of the mirror. Besides, increasing the numbers of the micro-mirrors will enlarge areas and enhance the reflective light. The DMD is a basic semiconductor device and is controlled by a two-bit pulse. It is a high speed and reflective digital optical switch which can control the angle of the reflective light precisely and thereby control the intensity of the light.

To sum up, the photomask 10 can be reused according to the difference between the new or old design of products, because the shading patterns formed with transparent, gray-scale and opaque patterns are alterable. Therefore, it is unnecessary to manufacture different traditional photomasks, so that the processes and the layout design can be modified efficiently to obtain the optimum parameters of the exposure process and to reduce the time for inspection and modification of new products.

While the above mentions are some better examples for demonstration, but not the limitation of application in this invention. All the homogeneous modification and variations of the invention are included in what is claimed in this invention.

What is claimed is:

1. A photomask with controllable patterns, comprising
the photomask which is a panel with controllable and alterable shading patterns.

2. The photomask with controllable patterns of claim 1, wherein the panel is composed of arrays of a plurality of optical controlled elements.

3. The photomask with controllable patterns of claim 1, wherein the photomask is a transmissive liquid crystal panel.

4. The photomask with controllable patterns of claim 1, wherein the photomask is a liquid crystal panel having a reflective layer.

5. The photomask with controllable patterns of claim 1, wherein the photomask is a transmissive electronic paper.

6. The photomask with controllable patterns of claim 1, wherein the photomask is an electronic paper having a reflective layer.

7. The photomask with controllable patterns of claim 1, wherein the photomask is a digital micro-mirror device (DMD).
